(19) United States
(12) Patent Application Publication
(10) Pub. No.: US 2026/0079199 A1
(43) Pub. Date: Mar. 19, 2026

(54) METHOD AND APPARATUS FOR PERFORMING INSTRUMENT-FREE CALIBRATION

(71) Applicant: MEDIATEK INC., Hsinchu City (TW)

(72) Inventors: Chi-Tsan Chen, Hsinchu City (TW); Chieh-Hsun Hsiao, Hsinchu City (TW); Po-Sen Tseng, Hsinchu City (TW); Jen-Wei Ko., San Jose, CA (US)

(73) Assignee: MEDIATEK INC., Hsinchu City (TW)

(21) Appl. No.: 19/329,574

(22) Filed: Sep. 16, 2025

Related U.S. Application Data
(60) Provisional application No. 63/696,410, filed on Sep. 19, 2024.

(51) Int. Cl. G01R 31/28; H03F 3/04; H03K 5/1252

(52) U.S. Cl. CPC G01R 31/2884; H03F 3/04; H03K 5/1252

(57) ABSTRACT

An electronic device includes a first integrated circuit and a second integrated circuit. The first integrated circuit includes a test tone generator circuit used to generate a test tone signal during a calibration procedure. A first test signal output from the first integrated circuit is generated according to the test tone signal. The second integrated circuit includes a power detector circuit used to perform power detection upon a second test signal for generating a power detection value during the calibration procedure. The second test signal is derived from the first test signal, and calibration of at least one of the first integrated circuit and the second integrated circuit is based on the power detection value.

### CROSS REFERENCE TO RELATED APPLICATIONS

This application claims the benefit of U.S. Provisional Application No. 63/696,410, filed on Sep. 19, 2024. The content of the application is incorporated herein by reference.

### BACKGROUND

The present invention relates to a calibration scheme, and more particularly, to a method and apparatus for performing instrument-free calibration with the aid of a test tone generator circuit embedded in one integrated circuit and a power detector circuit embedded in another integrated circuit.

An electronic device may include a plurality of integrated circuits (also called chips) to deal with a plurality of signal processing tasks, respectively. An interface between two integrated circuits (ICs) may have various implementation options. For example, one IC may be connected to another IC via a coaxial cable. For another example, one IC may be connected to another IC via a flexible printed circuit (FPC). For yet another example, one IC may be connected to another IC via a printed circuit board (PCB). For different types of an interface between two ICs, the insertion loss of the interface varies a lot. It is critical to have a proper signal operating point at the interface to ensure an overall system performance. However, without the knowledge of the path loss of the interface, it is difficult to control the signal operating point. Thus, there is a need for an efficient and cost-effective calibration scheme to characterize interface path loss and apply calibration for achieving optimal system performance.

### SUMMARY

One of the objectives of the claimed invention is to provide a method and apparatus for performing instrument-free calibration with the aid of a test tone generator circuit embedded in one integrated circuit and a power detector circuit embedded in another integrated circuit.

According to a first aspect of the present invention, an exemplary electronic device is disclosed. The exemplary electronic device includes a first integrated circuit and a second integrated circuit. The first integrated circuit includes a test tone generator circuit configured to generate a test tone signal during a calibration procedure, wherein a first test signal output from the first integrated circuit is generated according to the test tone signal. The second integrated circuit includes a power detector circuit configured to perform power detection upon a second test signal for generating a power detection value during the calibration procedure, wherein the second test signal is derived from the first test signal, and calibration of at least one of the first integrated circuit and the second integrated circuit is based on the power detection value.

According to a second aspect of the present invention, an exemplary calibration method is disclosed. The exemplary calibration method includes: generating, by a first integrated circuit, a test tone signal; generating and outputting a first test signal to a second integrated circuit according to the test tone signal; performing, by the second integrated circuit, power detection upon a second test signal to generate a first power detection value, wherein the second test signal is derived from the first test signal; and calibrating at least one of the first integrated circuit and the second integrated circuit according to the first power detection value.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an electronic device that supports the proposed instrument-free calibration scheme according to an embodiment of the present invention.

FIG. 2 is a flowchart of a calibration method according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

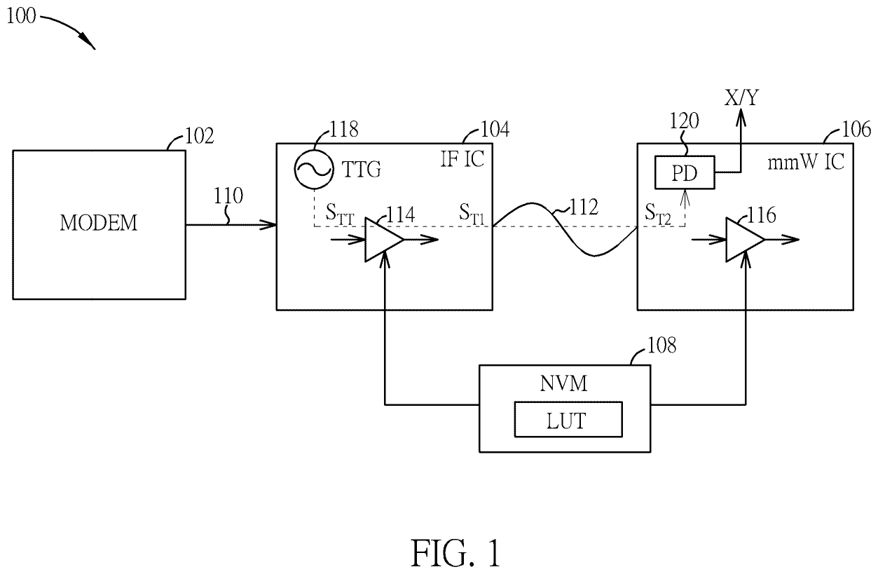

FIG. 1 is a diagram illustrating an electronic device that supports the proposed instrument-free calibration scheme according to an embodiment of the present invention. By way of example, but not limitation, the electronic device 100 may be a wireless communication device such as a millimeter wave (mmW) cellular radio system. As shown in FIG. 1, the electronic device 100 may include a modulator/demodulator (MODEM) 102, an intermediate frequency (IF) IC 104, an mmW IC 106, and a non-volatile memory (NVM) 108. The IF IC 104 may include an amplifier circuit 114 for providing amplification of an IF signal. The mmW IC 106 may include an amplifier circuit 116 for amplification of an mmW signal. It should be noted that only the components pertinent to the present invention are illustrated in FIG. 1. In practice, the electronic device 100 may include additional components to achieve its designated function, the IF IC 104 may include additional components to achieve its designated function, and the mmW IC 106 may include additional components to achieve its designated function.

The MODEM 102 may be a part of a baseband IC, and is connected to the IF IC 104 through an interface 110. The IF IC 104 is connected to the mmW IC 106 through an interface 112. The interface 112 between IF IC 104 and mmW IC 106 may have various implementation options. For example, the interface 112 may be a coaxial cable, an FPC, or a PCB. For different types of the interface 112, the insertion loss of the interface 112 varies a lot, as illustrated in the following table.

TABLE 1

| | |
|---|---|
| Type of | Insertion Loss (dB/cm) |

| Interface | @ 1 GHz | @ 9 GHz | @ 16 GHz |
|---|---|---|---|
| PCB | 0.12 | 0.60 | 1.00 |
| FPC | 0.11 | 0.44 | 0.67 |
| Coaxial Cable | 0.04 | 0.14 | 0.18 |

Different types of the interface 112 have different levels of path loss, which will result in different power link budget requirements. Ideally, the transmit (TX) power needs to overcome the path loss, and it can't exceed the dynamic range of the receiver. However, without the knowledge of the path loss of the interface 112, it would be difficult to control the signal operating point at the interface 112. Assuming that the output power Pout of the IF IC 104 is fixed, different cases under different levels of path loss are illustrated in the following table.

TABLE 2

| Power Link | Pout of IF | Interface Path | Pout of mmW |
|---|---|---|---|
| Budget | IC (dBm) | Loss (dB) | IC (dBm) |
| Case #1 | −15 | −7 | 16 |
| Case #2 | −15 | −3 | 18.x |
| Case #3 | −15 | −11 | 12 |

In Case #1,the power link budget shows a nominal output power Pout=16 dBm at the mmW IC 106, resulting in good Equivalent Isotropic Radiated Power (EIRP) and good Error Vector Magnitude (EVM). In Case #2, due to the lower interface path loss, the amplifier circuit 116 at the mmW IC 106 is over-driven to operate in a saturation region for generating an output power Pout around 18 dBm, resulting in boosted EIRP and degraded EVM. In Case #3, due to the higher interface path loss, the amplifier circuit 116 at the mmW IC 106 is operating at a backed-off region to generate an output power Pout=12 dBm, resulting in degraded EIRP and boosted EVM. If information of the interface path loss can be available, the signal level at the interface 112 can be properly adjusted/calibrated to achieve the optimal system performance (e.g., good EIRP and good EVM). To address this interface path loss issue, the present invention proposes an efficient and cost-effective calibration scheme (e.g., an instrument-free calibration scheme) to characterize the path loss of the interface 112 and perform necessary calibration for system performance improvement.

In accordance with the proposed instrument-free calibration scheme, the IF IC 104 has a test tone generator circuit (labeled by “TTG”) 118 embedded therein, and the mmW IC 106 has a power detector circuit (labeled by “PD”) 120 embedded therein. The test tone generator circuit 118 is configured to generate a test tone signal S_{TT} during a calibration procedure of the electronic device 100. A test signal S_{T1} output from the IF IC 104 to the mmW IC 106 is generated according to the test tone signal S_{TT}. For example, the amplifier circuit 114 is involved in generation of the test signal Sri, which includes amplification of the test tone signal Str. The power detector circuit 120 is configured to perform power detection upon a test signal S_{T2} for generating at least one power detection value X/Y during the calibration procedure of the electronic device 100. As shown in FIG. 1, the test signal S_{T2} is derived from the test signal Sri that is transmitted from the IF IC 104 to the mmW IC 106 over the interface 112. In addition, calibration of at least one of the IF IC 104 and the mmW IC 106 (particularly, one or both of the amplifier circuits 114 and 116) is based on the power detection value X. Further details of the proposed instrument-free calibration scheme are described as below with reference to the accompanying flowchart.

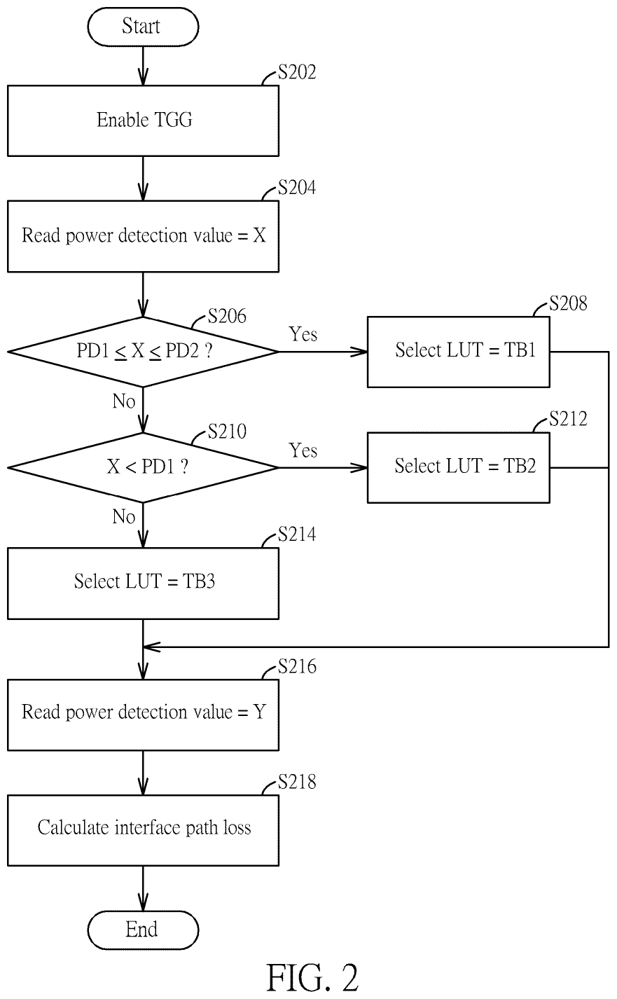

FIG. 2 is a flowchart of a calibration method according to an embodiment of the present invention. Provided that the result is substantially the same, the steps are not required to be executed in the exact order shown in FIG. 2. By way of example, but not limitation, the calibration flow may be managed by a control program running on a processor (not shown). The calibration method is performed without any external instrument involved. In this embodiment, the instrument-free calibration is achieved with the aid of the test tone generator circuit 118 embedded in the IF IC 104 and the power detector circuit 120 embedded in the mmW IC 106. When the calibration procedure starts, the test tone generator circuit 118 is enabled by the control program running on the processor (step S202). Hence, after the test tone generator circuit 118 is enabled, the test signal Smi is generated and output from the IF IC 104 to the mmW IC 106. The test signal Sri is derived from the test tone signal S_{TT}. For example, the test tone signal Sur may be an input signal of the amplifier circuit 114, and the test signal Sri may be an output signal of the amplifier circuit 114.

The non-volatile memory 108 is used to store a gain table LUT that records gain settings of at least one of the amplifier circuits 114 and 116. For example, a gain of the amplifier circuit 114 may be controlled/adjusted by gain settings recorded in the gain table LUT, and a gain of the amplifier circuit 116 may be a pre-defined value. For another example, a gain of the amplifier circuit 116 may be controlled/adjusted by gain settings recorded in the gain table LUT, and a gain of the amplifier circuit 114 may be a pre-defined value. For yet another example, a gain of the amplifier circuit 114 and a gain of the amplifier circuit 116 may be both controlled/adjusted by gain settings recorded in the gain table LUT. Initially, the gain table LUT may be set by a default table. For example, the default table may be one of a plurality of pre-defined tables TB1, TB2, TB3 with different gain settings. In step S204, the power detector circuit 120 performs power detection upon the test signal S_{T2} to generate and output a power detection value X to the control program running the processor. Specifically, the power detection value X is read under a condition that the gain table LUT is set by the default table.

In this embodiment, the test signal S_{T2} is an input signal received by the mmW IC 106 during the calibration procedure. Hence, the test signal S_{T2} at the mmW IC 106 is generated by transmitting the test signal Smi over the interface 112. Since the test tone signal S_{TT} is a sinusoidal wave with known magnitude and the gain of the amplifier circuit 114 has a known value (e.g., a default value), the power detection value X is indicative of the path loss of the interface 112. However, the power detector circuit 120 may be implemented using a simple detector with a limited power detection range. Hence, the power detector circuit 120 implemented using a single detector with a limited power detection range may be incapable of obtaining an accurate power detection value. Furthermore, when the power of the test signal S_{T2} is beyond the limited power detection range of the power detector circuit 120, the power detection value X is a clipped value indicative of an upper bound or a lower bound of the limited power detection range. To address this limited power detection range issue, the proposed instrument-free calibration scheme enhances the calibration robustness by comparing the power detection value X with one or more pre-defined threshold values. That is, the proposed instrument-free calibration scheme compares the power detection value X with one or more pre-defined threshold values to identify a power range in which the test signal S_{T2} is located.

After obtaining the power detection value X, the control program running on the processor compares the power detection value X with two pre-defined threshold values PD1 and PD2 (PD2>PD1), and selects a target table from a plurality of candidate tables (e.g., TB1, TB2, and TB3) according to the comparison result. If the power detection value X is not smaller than the pre-defined threshold value PD1 and is not larger than the pre-defined threshold value PD2 (i.e., P1≤X≤PD2), the pre-defined table TB1 is selected for setting the gain table LUT (steps S206 and S208). If the power detection value X is smaller than the pre-defined threshold value PD1 (i.e., X<PD1), indicating that the power of the test signal S_{T2} may be too low (e.g., the power detection value X may be clipped due to the lower bound of the limited power detection range of the power detector circuit 120), the pre-defined table TB2 is selected for setting the gain table LUT (steps S210 and S212). If the power detection value X is larger than the pre-defined threshold value PD2 (i.e., X>PD2), indicating that the power of the test signal S_{T2} may be too high (e.g., the power detection value X may be clipped due to the upper bound of the limited power detection range of the power detector circuit 120), the pre-defined table TB3 is selected for setting the gain table LUT (steps S210 and S214).

It should be noted that the pre-defined threshold values PD1 and PD2 may be adjusted, depending upon actual design considerations. In some embodiments of the present invention, the number of pre-defined tables and the number of pre-defined threshold values may be adjusted, depending upon actual design considerations. In some embodiments of the present invention, gain settings recorded in pre-defined tables TB1, TB2, TB3 may be adjusted, depending upon actual design considerations.

With a proper selection of the gain table LUT under a calibration mode, one or both of the amplifier circuits 114 and 116 can be calibrated to ensure that the output power of the mmW IC 106 under a normal mode is within a desired power range for achieving the optimal system performance (e.g., good EIRP and good EVM). For example, the calibration method shown in FIG. 2 may be performed during mass production of electronic devices 100 in a factory. For another example, the calibration method shown in FIG. 2 may be performed during maintenance/repair of the electronic device 100 in a service store.

After the gain table LUT is set by a target table selected from comparing the power detection value X with one or more pre-defined threshold values, the power detector circuit 120 performs power detection upon the test signal Sr: to generate and output another power detection value Y to the control program running the processor (step S216). The power detection value Y is obtained under a condition that the power of the test signal S_{T2} is within the limited power detection range of the power detector circuit 120. Since the test tone signal S_{TT} is a sinusoidal wave with known magnitude and the gain of the amplifier circuit 114 is set by a known value that is configured by the gain table LUT, the power detection value Y is indicative of the path loss of the interface 112. Hence, the control program running the processor can calculate the path loss of the interface 112 according to at least the power detection value Y (step S218). For example, an estimate of the path loss of the interface 112 can be used by other power control applications.

Regarding the embodiment shown in FIG. 1, the proposed instrument-free calibration scheme is used to characterize the interface path loss and calibrate one or both of wireless communication ICs (i.e., IF IC 104 and mmW IC 106) to achieve the optimal system performance. However, this is for illustrative purposes only, and is not meant to be a limitation of the present invention. The same instrument-free calibration concept can be applied to any electronic device with two ICs encountering an interface path loss issue. For example, the IF IC 104 may be replaced by a first IC with one designated function, and the mmW IC 106 may be replaced by a second IC with another designated function, where the first IC is designed to include the embedded test tone generator circuit 118, and the second IC is designed to include the embedded power detector circuit 120. These alternative designs all fall within the scope of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic device comprising:
a first integrated circuit (IC), comprising:
a test tone generator circuit, configured to generate a test tone signal during a calibration procedure, wherein a first test signal output from the first IC is generated according to the test tone signal; and
a second IC, comprising:
a power detector circuit, configured to perform power detection upon a second test signal for generating a power detection value during the calibration procedure, wherein the second test signal is derived from the first test signal, and calibration of at least one of the first IC and the second IC is based on the power detection value.

2. The electronic device of claim 1, wherein the electronic device is a wireless communication device.

3. The electronic device of claim 2, wherein the first IC is an intermediate frequency (IF) IC.

4. The electronic device of claim 2, wherein the second IC is a millimeter wave (mmW) IC.

5. A calibration method comprising:
generating, by a first integrated circuit (IC), a test tone signal;
generating and outputting a first test signal to a second IC according to the test tone signal;
performing, by the second IC, power detection upon a second test signal to generate a first power detection value, wherein the second test signal is derived from the first test signal; and
calibrating at least one of the first IC and the second IC according to the first power detection value.

6. The calibration method of claim 5, wherein the first IC comprises a first amplifier circuit, the second IC comprises a second amplifier circuit, and calibrating the at least one of the first IC and the second IC according to the first power detection value comprises:
comparing the first power detection value with at least one pre-defined threshold value to generate a comparison result;
selecting a target table from a plurality of candidate tables according to the comparison result; and
configuring at least one of the first amplifier circuit and the second amplifier circuit according to gain settings recorded in the target table.

7. The calibration method of claim 6, further comprising:
after the at least one of the first amplifier circuit and the second amplifier circuit is calibrated according to the target table, performing, by the second IC, power detection upon the second test signal to generate a second power detection value; and
estimating a path loss between the first IC and the second IC according to at least the second power detection value.

8. The calibration method of claim 5, wherein each of the first IC and the second IC is a wireless communication IC.

9. The calibration method of claim 8, wherein the first IC is an intermediate frequency (IF) IC.

10. The calibration method of claim 8, wherein the second IC is a millimeter wave (mmW) IC.
